(19) United States
(12) Patent Application Publication
(10) Pub. No.: US 2020/0039813 A1
(43) Pub. Date: Feb. 6, 2020

(54) MEMS DEVICE

(71) Applicant: KABUSHIKI KAISHA TOSHIBA, Minato-ku (JP)

(72) Inventors: Akira Fujimoto, Kawasaki Kanagawa (JP); Yoshihiko Kurui, Chigasaki Kanagawa (JP); Hideyuki Tomizawa, Ota Gumma (JP); Tomohiro Saito, Yokohama Kanagawa (JP); Akihiro Kojima, Suginami Tokyo (JP)

(73) Assignee: KABUSHIKI KAISHA TOSHIBA, Minato-ku (JP)

(21) Appl. No.: 16/352,376

(22) Filed: Mar. 13, 2019

(30) Foreign Application Priority Data
Aug. 1, 2018 (JP) 2018-145204

(51) Int. Cl. B81B 3/00; B81B 7/00

(52) U.S. Cl. CPC B81B 3/0037; B81B 7/007; B81B 3/0067; B81B 3/0021

(57) ABSTRACT

According to one embodiment, a MEMS device is disclosed. The MEMS device includes a substrate, and a MEMS vibrator provided on the substrate. The MEMS vibrator includes a first vibration portion disposed above the substrate, and a control electrode to control a vibration property of the first vibration portion. The control electrode is disposed without contacting the first vibration portion.

### CROSS-REFERENCE TO RELATED APPLICATIONS

This application is based upon and claims the benefit of priority from Japanese Patent Application No. 2018-145204, filed Aug. 1, 2018, the entire contents of which are incorporated herein by reference.

### FIELD

Embodiments described herein relate generally to a micro-electromechanical systems (MEMS) device.

### BACKGROUND

A MEMS resonator has been known as one of devices (MEMS devices) formed with MEMS technology. The MEMS resonator includes, for example, a substrate, a vibrator having the form of a disk, an anchor, and a fixed electrode. The vibrator is supported above the substrate by the anchor. The fixed electrode is disposed along a side surface of the vibrator. The vibrator vibrates to change a distance between its side surface and a detection electrode. Regarding the MEMS resonator, it has been required that the vibrator vibrates at a predetermined frequency and the MEMS resonator be able to be driven with low power.

### BRIEF DESCRIPTION OF THE DRAWINGS

FIG. 1 is a plan view showing a MEMS resonator according to a first embodiment.

FIG. 2 is a sectional view taken along a line 2-2 in FIG. 1.

FIGS. 3A, 3B, 3C, 3D, 3E, and 3F are sectional views for explaining an example of a method of manufacturing the MEMS resonator according to the first embodiment.

FIGS. 4A, 4B, 4C, and 4D are plan views showing modified examples of a control electrode.

FIG. 5 is a plan view showing a MEMS resonator according to a second embodiment.

FIG. 6 is a plan view showing a MEMS resonator of a comparative example.

FIG. 7 is a plan view showing a MEMS resonator according to a third embodiment.

FIG. 8 is a diagram for explaining an effect of the MEMS resonator according to the third embodiment.

FIG. 9 is a plan view showing a MEMS resonator according to a fourth embodiment.

FIG. 10 is a plan view showing a modified example of the MEMS resonator according to the fourth embodiment.

FIG. 11 is a plan view showing a MEMS resonator according to a fifth embodiment.

FIG. 12 is a plan view showing a modified example of the MEMS resonator according to the fifth embodiment.

FIG. 13 is a plan view showing a modified example of a MEMS resonator according to a sixth embodiment.

FIG. 14 is a plan view showing a MEMS gas sensor according to a seventh embodiment.

FIG. 15 is a sectional view taken along a line 15-15 in FIG. 14.

### DETAILED DESCRIPTION

In general, according to one embodiment, a MEMS device is disclosed. The MEMS includes a substrate, and a MEMS vibrator provided on the substrate. The MEMS vibrator includes a first vibration portion disposed above the substrate, and a control electrode to control a vibration property of the first vibration portion. The control electrode is disposed without contacting the first vibration portion.

Embodiments will be described hereinafter with reference to the accompanying drawings. The drawings are schematic or conceptual drawings, and dimensions and ratios are not necessarily the same as those in reality. Further, in the drawings, the same reference symbols (including those having different subscripts) denote the same or corresponding parts, and overlapping explanations thereof will be made as necessary. In addition, as used in the description and the appended claims, what is expressed by a singular form shall include the meaning of “more than one”.

### First Embodiment

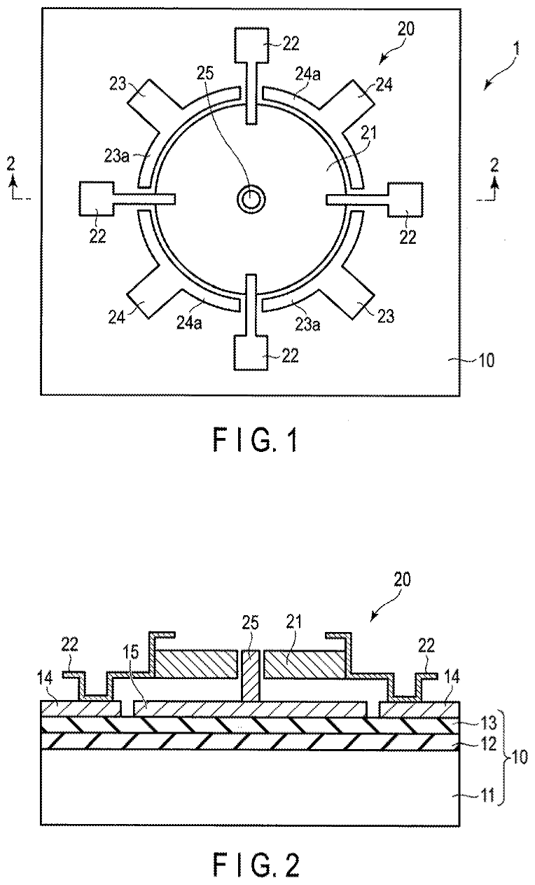

FIG. 1 is a plan view showing a MEMS resonator (MEMS device) 1 according to a first embodiment. FIG. 2 is a sectional view taken along a line 2-2 of FIG. 1.

The MEMS resonator 1 includes a substrate 10 and a MEMS vibrator 20 provided on the substrate 10.

The substrate 10, for example, has a structure in which a silicon substrate 11, a silicon oxide film 12, and a silicon nitride film 13 are stacked in this order as shown in FIG. 2.

The MEMS vibrator 20 includes a mechanical vibrator (first vibration portion) 21 disposed above the substrate 10, anchors (support portions) 22 which support the vibrator 21 on the substrate 10, detection electrodes 23 fixed on the substrate 10, and driving electrodes 24 fixed on the substrate 10, and a control electrode 25 passing through a through-hole provided in the vibrator 21.

A material for the vibrator 21 is, for example, SiₓGe₁₋ₓ (0≤x≤1), GaAs, AlN, or PZT. The planar shape of the vibrator 21 is a circle in FIG. 1. However, the planar shape may be an ellipse, a square, a rectangle, or a polygon having five or more sides.

The detection electrodes 23 include portions 23a which are disposed to face parts of a side surface of the vibrator 21 without contacting the side surface of the vibrator 21. The distance between the portions 23a and the side surface of the vibrator 21 is, for example, 100 to 2,000 nm. The driving electrodes 24 include portions 24a which are disposed to face parts of the side surface of the vibrator 21 without contacting the side surface of the vibrator 21. The distance between the portions 24a and the side surface of the vibrator 21 is, for example, 100 to 2,000 nm.

The control electrode 25 is disposed without contacting the vibrator 21. More specifically, the control electrode 25 is disposed to pass through the through-hole provided in the vibrator 21. The distance between the vibrator 21 and a side surface of the through-hole is, for example, 100 to 2,000 nm. In addition, the area of a top surface of the control electrode 25 is, for example, 0.1 to 50% of the area of a top surface of the vibrator 21. If the area of the top surface of the control electrode 25 is less than 0.1% of the area of the top surface of the vibrator 21, it is hard to control vibration frequency of the vibrator 21 by a voltage applied to the control electrode 25. If the area of the top surface of the control electrode 25 is more than 50% of the area of the top surface of the vibrator 21, it is hard for the vibrator 21 to vibrate in a predetermined vibration mode (for example, a wineglass mode).

As shown in FIG. 2, an interconnection layer 14 is provided on the silicon nitride film 13. The anchors 22 are connected to the interconnection layer 14, and thereby fixed to the substrate 10. The anchors 22 support the vibrator 21 to allow the vibrator 21 to vibrate. Moreover, the anchors 22 are electrically connected to the vibrator 21. An interconnection layer 15 is further provided on the silicon nitride film 13. The control electrode 25 is connected to the interconnection layer 15, and thereby fixed to the substrate 10. The detection electrodes 23 are connected to an interconnection layer (not shown in the figures) provided on the silicon nitride film 13, and thereby fixed to the substrate 10. Similarly, the driving electrodes 24 are connected to an interconnection layer (not shown in the figures) provided on the silicon nitride film 13, and thereby fixed to the substrate 10.

When an AC voltage is applied between the anchors 22 and the driving electrodes 24, the distance between the side surface of the vibrator 21 and the detection electrodes 23 changes, and the vibrator 21 vibrates. If a capacitance detector is connected between a pair of detection electrodes 23, a vibration frequency of the vibrator can be acquired based on the output of the capacitance detector. A resonant frequency of the vibrator 21 is, for example, between 1 MHz and 1 GHz. The vibration amplitude of the vibrator 21 is, for example, 2 to 3 nm. The above AC voltage may be applied from an AC power source (not shown in the figures) provided outside the MEMS resonator 1, or may be applied from an AC power source (not shown in the figures) provided in the MEMS resonator 1.

When a predetermined DC voltage (control voltage) is applied to the control electrode 25, the vibration properties of the vibrator 21 are controlled. In the present embodiment, the control voltage is applied to the control electrode 25 via the interconnection layer 15. The control voltage may vary from MEMS resonator to MEMS resonator. Thus, the value of the control voltage is determined after the MEMS resonator 1 is manufactured.

The control voltage may be applied from a power source (not shown in the figures) provided outside the MEMS resonator 1, or may be applied from a power source (not shown in the figures) provided in the MEMS resonator 1. If a variable power source is used as the power source, a control voltage varying from MEMS resonator to MEMS resonator can easily be applied.

According to the present embodiment, since the control electrode 25 is used, the vibrator 21 can be controlled to vibrate at a predetermined frequency. For example, the vibrator 21 can be controlled to vibrate at its resonant frequency or to vibrate in a predetermined vibration mode (for example, a wineglass mode).

In addition, since the control electrode 25 is provided in a region where the vibrator 21 is disposed, the areas of the detection electrodes 23 and the driving electrodes 24 are not reduced. As a result, an increase in the power consumption of a driving circuit due to an increase in motion resistance can be suppressed.

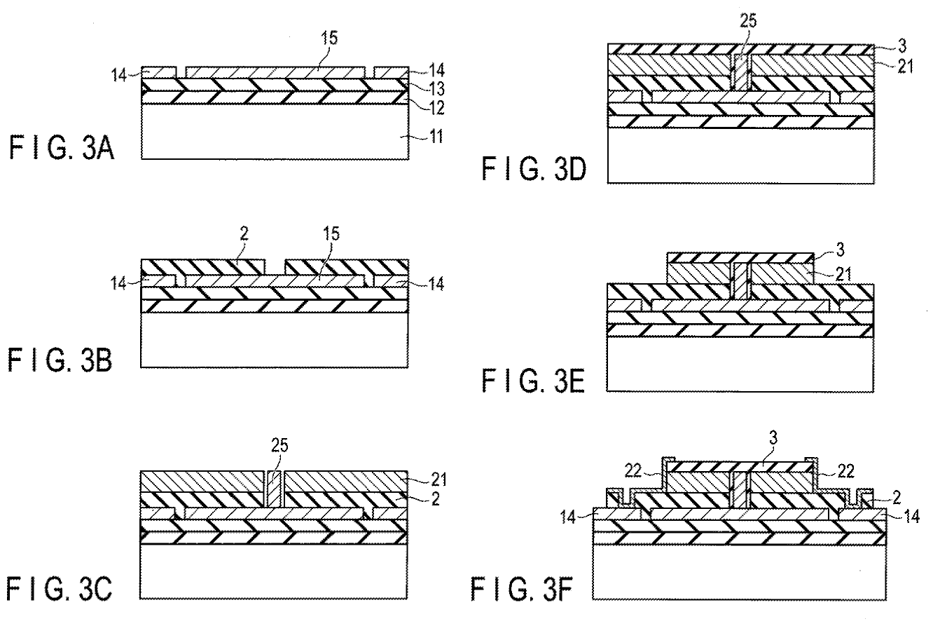

The MEMS resonator 1 can be manufactured by using a well-known sacrificial film process. FIG. 3A to FIG. 3F are sectional views for explaining an example of a method of manufacturing the MEMS resonator 1.

First, as shown in FIG. 3A, the silicon oxide film 12 and the silicon nitride film 13 are formed on the silicon substrate 11 in this order, and then, the interconnection layer 14 and the interconnection layer 15 are formed by forming a conductive layer on the silicon nitride film 13 and patterning the conductive layer.

Next, as shown in FIG. 3B, a sacrificial film 2 is formed on the silicon nitride film 13 to fill a space between the interconnection layer 14 and the interconnection layer 15, and then, a through-hole reaching the interconnection layer 15 is formed in the sacrificial film 2. The sacrificial film 2 is herein a silicon oxide film.

Next, as shown in FIG. 3C, a SiₓGe₁₋ₓ film is formed on the sacrificial film 2 to fill the through-hole, and then, the vibrator 21 and the control electrode 25 are formed by patterning the SiₓGe₁₋ₓ film. At this stage, the vibrator 21 does not have the shape and dimensions shown in FIG. 1 and FIG. 2.

Next, as shown in FIG. 3D, a sacrificial film 3 is formed on the vibrator 21 and the control electrode 25 to fill a space between the vibrator 21 and the control electrode 25. The sacrificial film 3 is herein a silicon oxide film.

Next, as shown in FIG. 3E, a resist pattern (not shown in the figures) is formed on the sacrificial film 3, and the sacrificial film 3 and the vibrator 21 are etched by using the resist pattern used as a mask. The vibrator 21 having the shape and dimensions shown in FIG. 1 and FIG. 2 is thereby obtained.

Next, as shown in FIG. 3F, through-holes reaching the interconnection layer 14 are formed in the sacrificial film 2, and then, a SiₓGe₁₋ₓ film is formed to cover side surfaces and bottom surfaces of the through-holes. Then, the SiₓGe₁₋ₓ film is patterned to form the anchors 22.

Then, the sacrificial films 2 and 3 are removed, and the MEMS resonator 1 shown in FIG. 1 and FIG. 2 is thereby obtained.

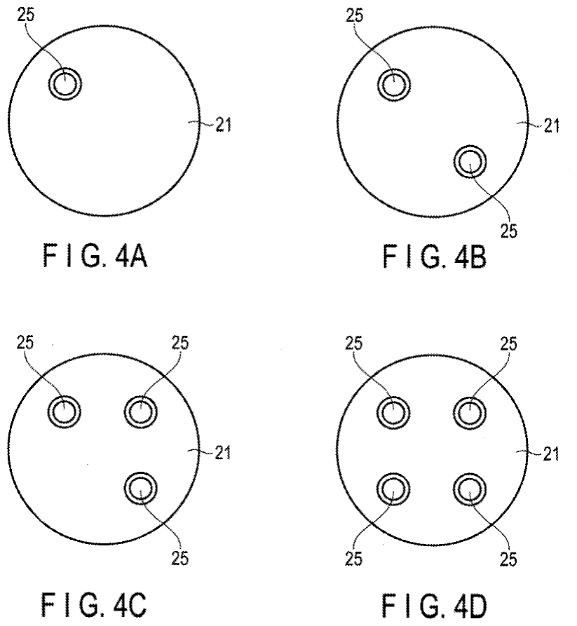

FIG. 4A to FIG. 4D are plan views showing modified examples of the control electrode 25.

In the present embodiment, the control electrode 25 is disposed to pass through the through-hole provided in a central portion of the vibrator 21. This is because the amplitude of resonance is small in the central portion of the vibrator 21. As shown in FIG. 4A, the control electrode 25 may be disposed to pass through a through-hole provided in a portion serving as a node of the vibration of the vibrator 21 (a portion where the amplitude of resonance is small). The portion serving as the node of the vibration depends on the resonance mode of the vibrator 21. In addition, although one control electrode 25 is used in the present embodiment, two or more control electrodes 25 may be used as shown in FIG. 4B to FIG. 4D. The two or more control electrodes 25 are disposed to pass through through-holes provided in portions serving as nodes of the vibration of the vibrator 21.

### Second Embodiment

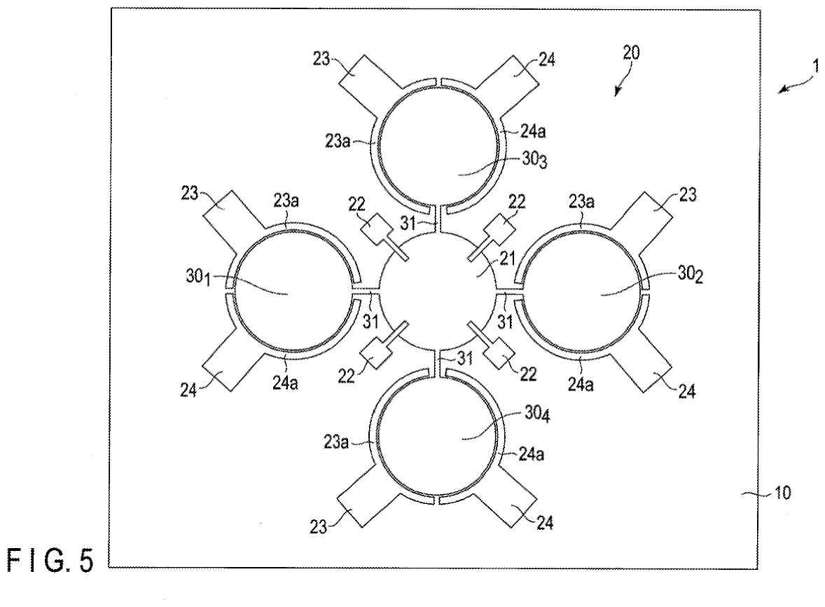

FIG. 5 is a plan view showing a MEMS resonator 1 according to a second embodiment.

The MEMS resonator 1 of the present embodiment includes a plurality of movable electrodes (vibration portions) 30₁ to 30₄ connected to a vibrator (vibration portion) 21 in parallel. The number of movable electrodes is not limited to four. Each of the movable electrodes 30₁ to 30₄ is connected to the vibrator 21 via a connecting portion 31. In the present embodiment, no though-hole is provided in the vibrator 21.

To suppress variations of vibration frequencies (resonant frequencies) of the vibrator 21 and the movable electrodes 30₁ to 30₄, the vibrator 21 and the movable electrodes 30₁ to 30₄ are formed so that they all have the same radius and thickness (that is, shape and dimensions). The distance between each of the movable electrodes 30₁ to 30₄ and a side surface of the vibrator 21 is, for example, 100 to 2,000 nm.

When an AC voltage is applied between anchors 22 and driving electrodes 24, the distance between side surfaces of the movable electrodes 30₁ to 30₄ and portions 23a of detection electrodes 23 changes, and the vibrator 21 and the movable electrodes 30₁ to 30₄ vibrate coordinately.

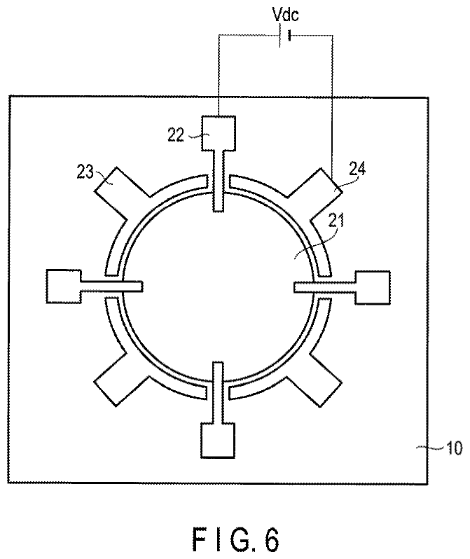

A motion resistance of the MEMS resonator 1 of the present embodiment is herein smaller than that of a MEMS resonator of a comparative example shown in FIG. 6. This point will be further described hereinafter.

The motion resistance Rₓ of the MEMS resonator of the comparative example is given by the following equations:

Rₓ=(ωᵣ/Q)·(mᵣₑ/ηₑ²) (1), and

ηₑ=Vdc·(ε₀·A/d²) (2),

where ωᵣ is an angular frequency at the time of the resonance of the vibrator 21, mᵣₑ is the effective mass of the vibrator 21, ηₑ is an electromechanical coupling coefficient, Vdc is a driving voltage, ε₀ is a dielectric constant of a vacuum, A is the facing area of the vibrator 21 and the detection (driving) electrodes 23, and d is the distance between the vibrator 21 and the detection (driving) electrodes 23.

In contrast, the motion resistance Rₓ′ of the MEMS resonator 1 of the present embodiment is given by the following equations:

Rₓ′=(ω₀/nQ)·(mᵣₑ/ηₑ′²) (3), and

ηₑ′=Vdc·(ε₀·nA/d²) (4)

where n is the number of movable electrodes.

When equation (4) is substituted into equation (3), the following equation is obtained:

Rₓ′=Rₓ/n³ (5)

As can be seen from equation (5), the motion resistance Rₓ′ is smaller than the motion resistance Rₓ. In the case of the MEMS resonator 1 comprising four movable electrodes shown in FIG. 6, Rₓ′ is a small value, which is ¼³(= 1/64) of Rₓ. Thus, according to the present embodiment, the MEMS resonator 1 can be driven by a low driving voltage, and as a result, the power consumption of a driving circuit of the MEMS resonator 1 can be reduced.

### Third Embodiment

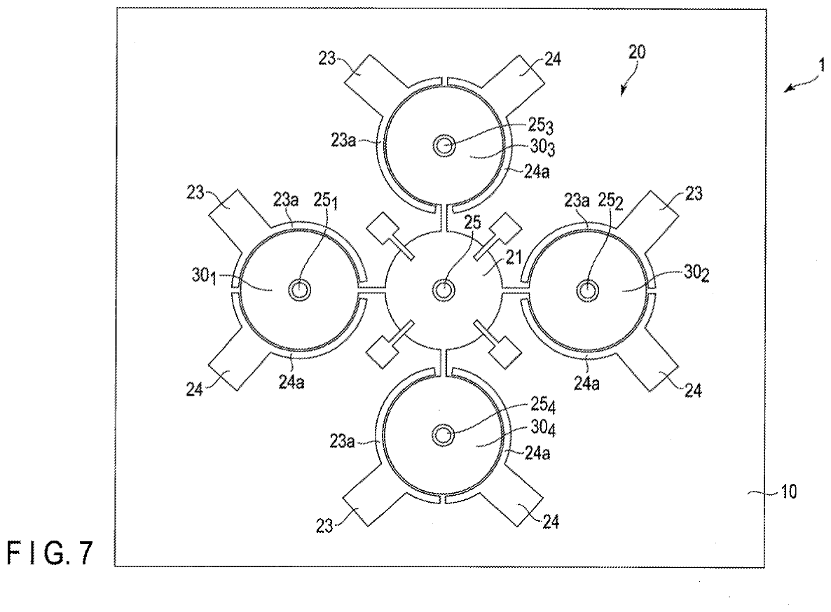

FIG. 7 is a plan view showing a HEMS resonator 1 according to a third embodiment.

The MEMS resonator 1 of the present embodiment differs from that of the second embodiment in that the control electrode described in the first embodiment is provided. More specifically, a control electrode 25 passing through a through-hole provided in a vibrator 21, and control electrodes 25₁ to 25₄ passing through through-holes provided in movable electrodes 30₁ to 30₄, respectively, are included.

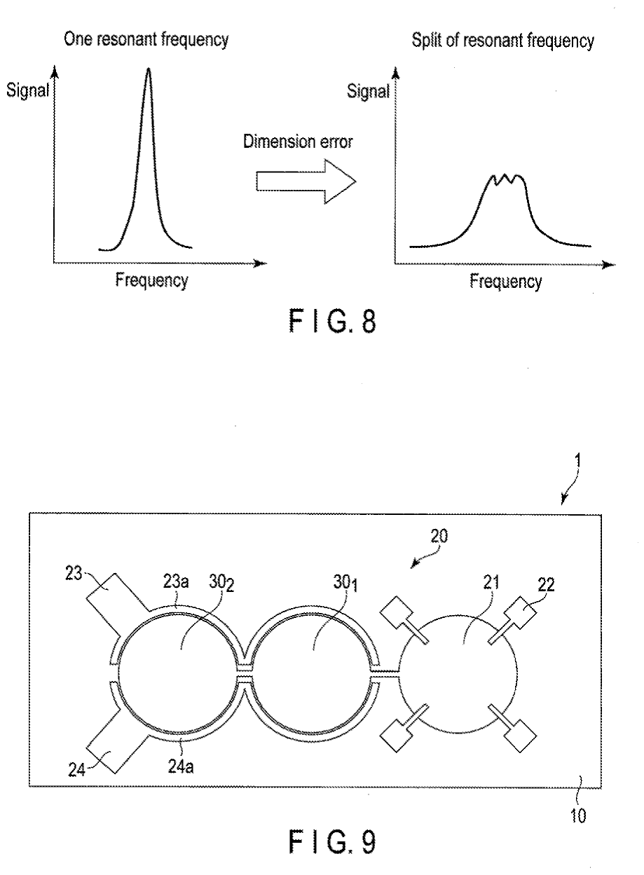

According to the present embodiment, the same effect as that of the second embodiment can be obtained. Moreover, according to the present embodiment, the vibrator 21 and the movable electrodes 30₁ to 30₄ can easily be controlled to vibrate at a predetermined frequency by adjusting a control voltage applied to each of the control electrodes 25 and 25₁ to 25₄. For example, even if a dimension error of the vibrator 21 and the movable electrodes 30₁ to 30₄ is caused in a manufacturing process, a split in resonant frequency as shown in FIG. 8 can be suppressed by adjusting the control voltage.

In the present embodiment, the vibrator 21 and the movable electrodes 30₁ to 30₄ are all provided with a control electrode. However, it is not necessarily required that all of them be provided with a control electrode. For example, it is possible that the control electrode 25 is provided but the control electrodes 25₁ to 25₄ are not provided. On the contrary, it is possible that the control electrode 25 is not provided but the control electrodes 25₁ to 25₄ are provided. That is, a structure including one or more of the control electrodes 25 and 25₁ to 25₄ is employed.

In addition, the control electrodes 25 and 25₁ to 25₄ may be disposed to pass through through-holes that are provided, not in central portions of the vibrator 21 and the movable electrodes 30₁ to 30₄, but in portions serving as nodes of the vibration of the vibrator 21 and the movable electrodes 30₁ to 30₄ as in the case of FIG. 4A to FIG. 4D.

### Fourth Embodiment

FIG. 9 is a plan view showing a MEMS resonator 1 according to a fourth embodiment.

The MEMS resonator 1 of the present embodiment comprises first and second movable electrodes 30₁ and 30₂ connected to a vibrator 21 in parallel. A motion resistance 1/N becomes smaller, by an amount corresponding to the number (N) of movable electrodes 30₁ and 30₂, as well as becoming smaller because of an increase in the facing area of a detection electrode 23 and the movable electrodes 30₁ and 30₂. The power consumption of a driving circuit thereby can be reduced. When the facing area of the detection electrode and the movable electrodes becomes n times greater, the motion resistance is 1/(Nn²).

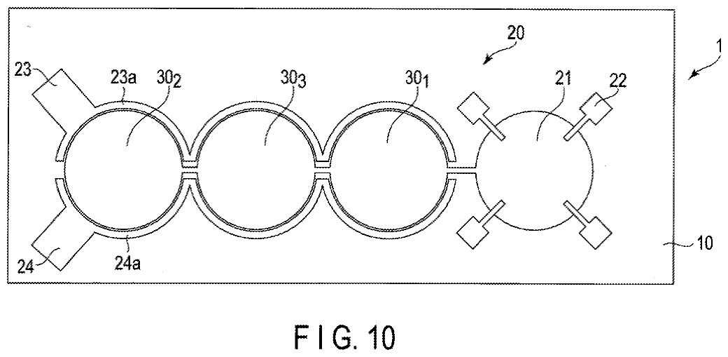

FIG. 10 is a plan view showing a modified example of the MEMS resonator 1 according to the present embodiment. This modified example further includes a third movable electrode 30₃ provided between the first movable electrode 30₁ and the second movable electrode 30₂. The second movable electrode 30₂ is indirectly connected to the vibrator 21 via the third movable electrode 30₃. The number of movable electrodes connected to the vibrator 21 in parallel may be four or more.

### Fifth Embodiment

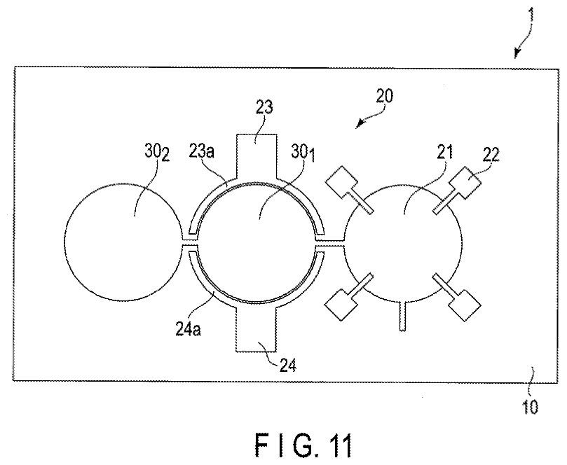

FIG. 11 is a plan view showing a MEMS resonator 1 according to a fifth embodiment.

The MEMS resonator 1 of the present embodiment comprises first and second movable electrodes 30₁ and 30₂ connected to a vibrator 21 in series. A Q factor (N·Q) becomes greater in proportion to the number (N) of movable electrodes 30₁ and 30₂, as well as becoming greater because of an increase in the facing area of a detection electrode 23 and the movable electrodes 30₁ and 30₂. Power consumption thereby can be reduced. When the facing area of the detection electrode and the movable electrodes becomes n times greater, a motion resistance is 1/(Nn²).

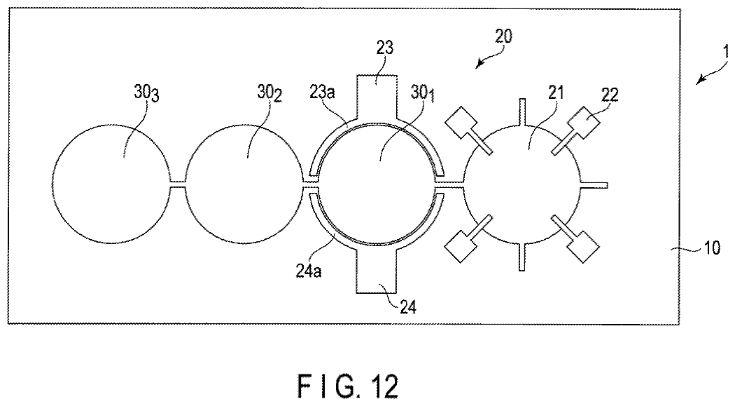

FIG. 12 is a plan view showing a modified example of the MEMS resonator 1 according to the present embodiment. This modified example further includes a third movable electrode 30₃ connected to the second movable electrode 30₂ in series. The third movable electrode 30₃ is indirectly connected to the vibrator 21 via the first and second movable electrodes 30₁ and 30₂. The number of movable electrodes connected to the vibrator 21 in series may be four or more.

### Sixth Embodiment

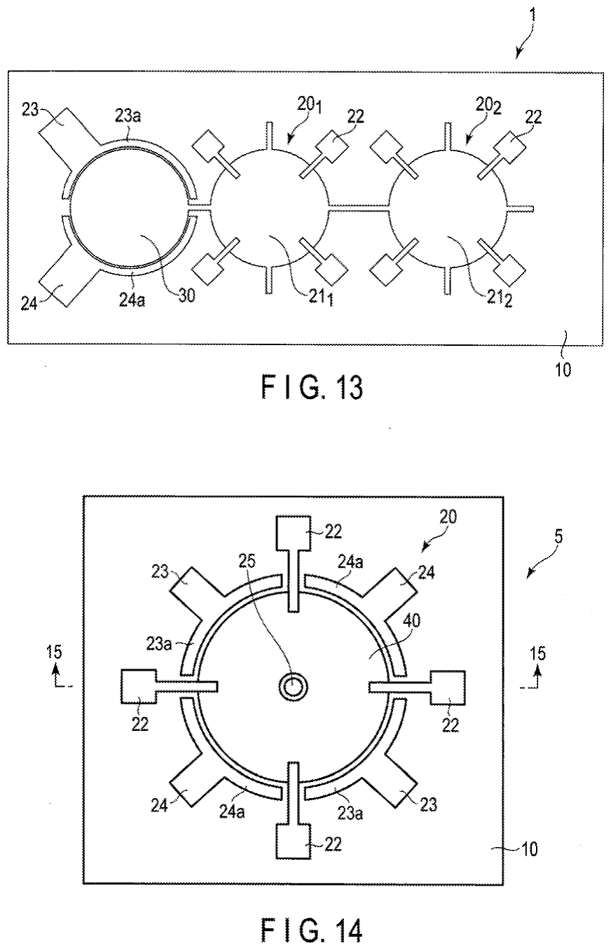

FIG. 13 is a plan view showing a MEMS resonator 1 according to a sixth embodiment.

The MEMS resonator 1 of the present embodiment comprises MEMS vibrators 20₁ and 20₂ connected in series, and a movable electrode 30₁ connected to the MEMS vibrator 20₁ in series. The number of MEMS vibrators is not limited to two, and the number of movable electrodes is not limited to one. A Q factor (N·Q) becomes greater in proportion to the number (N) of MEMS vibrators 20₁ and 20₂. Power consumption thereby can be reduced. When the facing area of a detection electrode and a movable electrode becomes n times greater, a motion resistance is 1/(Nn²).

### Seventh Embodiment

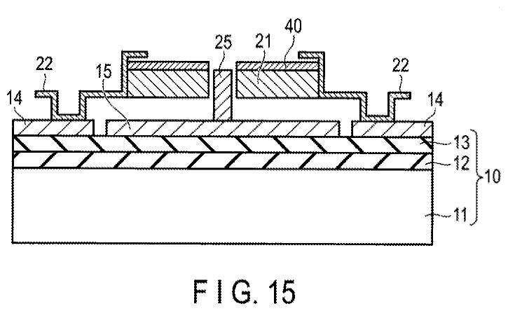

FIG. 14 is a plan view showing a MEMS gas sensor (MEMS device) 5 according to a seventh embodiment. FIG. 15 is a sectional view taken along a line 15-15 in FIG. 14.

The MEMS gas sensor 5 of the present embodiment comprises the MEMS resonator 1 of the first embodiment and a sensitive film 40 which is provided on a top surface of a vibrator 21 of the MEMS resonator 1 and which absorbs or adsorbs a predetermined gas (detection gas). The detection gas is, for example, a CO₂ gas.

When the sensitive film 40 absorbs the detection gas during a vibration of the vibrator 21, a vibration frequency of the vibrator 21 becomes lower. Thus, the detection gas can be detected on the basis of a change in the vibration frequency. In addition, the vibrator 21 can be vibrated at its resonant frequency by adjusting a voltage applied to a control electrode 25, and as a result, detection sensitivity can be increased.

Note that, the MEMS gas sensor 5 may be composed of any one of the MEMS resonators 1 of the second to sixth embodiments instead of the MEMS resonator 1 of the first embodiment.

Moreover, the MEMS resonators 1 of the first to sixth embodiments are applicable to other devices, such as oscillators, gyro sensors, or pressure sensors.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A MEMS device comprising:
a substrate; and
a MEMS vibrator provided on the substrate,
the MEMS vibrator comprising:
a first vibration portion disposed above the substrate; and
a control electrode configured to control a vibration property of the first vibration portion, the control electrode being disposed without contacting the first vibration portion.

2. The MEMS device of claim 1, wherein the control electrode passes through a through-hole provided in the first vibration portion.

3. The MEMS device of claim 1, further comprising a fixed electrode including a portion which is disposed to face a part of a side surface of the first vibration portion without contacting the side surface of the first vibration portion.

4. The MEMS device of claim 3, wherein the first vibration portion vibrates to change a distance between the side surface of the first vibration portion and the portion of the fixed electrode.

5. A MEMS device comprising:
a substrate; and
a MEMS vibrator provided on the substrate,
the MEMS vibrator comprising:
a first vibration portion which is disposed above the substrate and which has a first resonant frequency;
a second vibration portion which is connected to the first vibration portion and which has the first resonant frequency; and
a third vibration portion which is connected to any one of the first vibration portion and the second vibration portion and which has the first resonant frequency.

6. The MEMS device of claim 5, wherein the second vibration portion is connected to the first vibration portion, and
the third vibration portion is connected to the first vibration portion.

7. The MEMS device of claim 5, wherein the MEMS vibrator further comprises at least one of:
a first control electrode for controlling a vibration property of the first vibration portion, the first control electrode being disposed without contacting the first vibration portion;
a second control electrode for controlling a vibration property of the second vibration portion, the second control electrode being disposed without contacting the second vibration portion; and
a third control electrode for controlling a vibration property of the third vibration portion, the third control electrode being disposed without contacting the third vibration portion.

8. The MEMS device of claim 7, wherein the first control electrode, the second control electrode, and the third control electrode pass through through-holes provided in the first vibration portion, the second vibration portion, and the third vibration portion, respectively.

9. The MEMS device of claim 6, wherein the MEMS vibrator further comprises:
a first fixed electrode including a portion which is disposed to face a part of a side surface of the second vibration portion without contacting the side surface of the second vibration portion; and
a second fixed electrode including a portion which is disposed to face a part of a side surface of the third vibration portion without contacting the side surface of the third vibration portion.

10. The MEMS device of claim 9, wherein the first vibration portion, the second vibration portion, and the third vibration portion vibrate to change a distance between the side surface of the second vibration portion and the portion of the first fixed electrode and to change a distance between the side surface of the third vibration portion and the portion of the second fixed electrode.

11. The MEMS device of claim 5, wherein the second vibration portion is connected to the first vibration portion, and
the third vibration portion is connected to the second vibration portion.

12. The MEMS device of claim 11, further comprising a fixed electrode including a portion which is disposed to face a part of a side surface of the third vibration portion without contacting the side surface of the third vibration portion.

13. The MEMS device of claim 12, wherein the first vibration portion, the second vibration portion, and the third vibration portion vibrate to change a distance between the side surface of the third vibration portion and the portion of the fixed electrode.

14. The MEMS device of claim 1, further comprising a support portion which supports the first vibration portion on the substrate.

15. A MEMS device comprising:
a substrate;
a first MEMS vibrator disposed above the substrate and including a first vibration portion which has a first resonant frequency;
a second MEMS vibrator disposed above the substrate and including a second vibration portion which has the first resonant frequency and is connected to the first vibration portion; and
a third vibration portion which has the first resonant frequency and is connected to any one of the first vibration portion and the second vibration portion.

16. The MEMS device of claim 15, further comprising a fixed electrode including a portion which is disposed to face a part of a side surface of the third vibration portion without contacting the side surface of the third vibration portion.

17. The MEMS device of claim 16, wherein the first vibration portion, the second vibration portion, and the third vibration portion vibrate to change a distance between the side surface of the third vibration portion and the portion of the fixed electrode.

18. The MEMS device of claim 15, further comprising:
a support portion which supports the first vibration portion on the substrate; and
a support portion which supports the second vibration portion on the substrate.

19. The MEMS device of claim 1, further comprising a sensitive film provided on the vibration portion and configured to absorb or adsorb a predetermined gas.

20. The MEMS device of claim 19, wherein the predetermined gas includes carbon dioxide.
